(19) United States
(12) Patent Application Publication
(10) Pub. No.: US 2020/0144330 A1
(43) Pub. Date: May 7, 2020

(54) MULTI-CHANNEL VERTICAL TRANSISTOR FOR EMBEDDED NON-VOLATILE MEMORY

(71) Applicant: Intel Corporation, Santa Clara, CA (US)

(72) Inventors: Prashant MAJHI, San Jose, CA (US); Ravi PILLARISETTY, Portland, OR (US); Abhishek A. SHARMA, Hillsboro, OR (US); Brian S. DOYLE, Portland, OR (US); Elijah V. KARPOV, Portland, OR (US)

(21) Appl. No.: 16/630,851

(22) PCT Filed: Sep. 19, 2017
(86) PCT No.: PCT/US2017/052312

§ 371 Date: Jan. 13, 2020

(51) Int. Cl. H01L 27/24; H01L 45/00; H01L 29/786

(52) U.S. Cl. CPC H01L 27/2454; H01L 45/08; H01L 29/7869; H01L 29/78681; H01L 29/78672

(57) ABSTRACT

Multi-channel vertical transistors for embedded non-volatile memory are described. In an example, a memory array includes a plurality of non-volatile random access memory (RAM) elements. The memory array also includes a plurality of transistors. Individual ones of the plurality of transistors are coupled to corresponding individual ones of the plurality of non-volatile RAM elements. The plurality of transistors is a plurality of vertical multi-channel transistors.

### TECHNICAL FIELD

Embodiments of the disclosure are in the field of integrated circuit structures and, in particular, multi-channel vertical transistors for embedded non-volatile memory.

### BACKGROUND

For the past several decades, the scaling of features in integrated circuits has been a driving force behind an ever-growing semiconductor industry. Scaling to smaller and smaller features enables increased densities of functional units on the limited real estate of semiconductor chips.

For example, shrinking transistor size allows for the incorporation of an increased number of memory or logic devices on a chip, lending to the fabrication of products with increased capacity. The drive for ever-more capacity, however, is not without issue. The necessity to optimize the performance of each device becomes increasingly significant. In the manufacture of integrated circuit devices, multi-gate transistors, such as tri-gate transistors, have become more prevalent as device dimensions continue to scale down. In conventional processes, tri-gate transistors are generally fabricated on either bulk silicon substrates or silicon-on-insulator substrates. In some instances, bulk silicon substrates are preferred due to their lower cost and compatibility with the existing high-yielding bulk silicon substrate infrastructure. Scaling multi-gate transistors has not been without consequence, however. As the dimensions of these fundamental building blocks of microelectronic circuitry are reduced and as the sheer number of fundamental building blocks fabricated in a given region is increased, the constraints on the semiconductor processes used to fabricate these building blocks have become overwhelming.

The performance of a thin-film transistor (TFT) may depend on a number of factors. For example, the efficiency at which a TFT is able to operate may depend on the sub threshold swing of the TFT, characterizing the amount of change in the gate-source voltage needed to achieve a given change in the drain current. A smaller sub threshold swing enables the TFT to turn off to a lower leakage value when the gate-source voltage drops below the threshold voltage of the TFT. The conventional theoretical lower limit at room temperature for the sub threshold swing of the TFT is 60 millivolts per decade of change in the drain current.

Variability in conventional and state-of-the-art fabrication processes may limit the possibility to further extend them into the, e.g. 10 nm or sub-10 nm range. Consequently, fabrication of the functional components needed for future technology nodes may require the introduction of new methodologies or the integration of new technologies in current fabrication processes or in place of current fabrication processes.

### BRIEF DESCRIPTION OF THE DRAWINGS

FIG. 1A illustrates an angled view of a conventional one transistor one resistor (1T-1R) memory array.

FIG. 1B illustrates a plan view of taken through a cross-section of a pair of transistors of the array of FIG. 1A.

FIG. 2 illustrates an angled view of a one transistor one resistor (1T-1R) memory array, in accordance with an embodiment of the present disclosure.

FIG. 3 illustrates a plan view of taken through a cross-section of a pair of transistors of the array of FIG. 2, in accordance with an embodiment of the present disclosure.

FIGS. 4A-4D illustrate cross-sectional and corresponding plan views of various stages in a method of fabricating a multi-channel vertical transistors, in accordance with an embodiment of the present disclosure.

FIGS. 5A and 5B are top views of a wafer and dies that include multi-channel vertical transistors, in accordance with embodiments disclosed herein.

FIG. 6 illustrates a schematic of a memory bit cell which includes an RAM memory element, in accordance with an embodiment of the present disclosure.

FIG. 7 illustrates a block diagram of an electronic system, in accordance with an embodiment of the present disclosure.

FIG. 8 illustrates a computing device in accordance with one embodiment of the disclosure.

FIG. 9 illustrates an interposer that includes one or more embodiments of the disclosure.

### DESCRIPTION OF THE EMBODIMENTS

Multi-channel vertical transistors for embedded non-volatile memory are described. In the following description, numerous specific details are set forth, such as specific architectural and material regimes, in order to provide a thorough understanding of embodiments of the present disclosure. It will be apparent to one skilled in the art that embodiments of the present disclosure may be practiced without these specific details. In other instances, well-known features, such as single or dual damascene processing, are not described in detail in order to not unnecessarily obscure embodiments of the present disclosure. Furthermore, it is to be understood that the various embodiments shown in the Figures are illustrative representations and are not necessarily drawn to scale. In some cases, various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Certain terminology may also be used in the following description for the purpose of reference only, and thus are not intended to be limiting. For example, terms such as “upper”, “lower”, “above”, “below,” “bottom,” and “top” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

Embodiments described herein may be directed to front-end-of-line (FEOL) semiconductor processing and structures. FEOL is the first portion of integrated circuit (IC) fabrication where the individual devices (e.g., transistors, capacitors, resistors, etc.) are patterned in the semiconductor substrate or layer. FEOL generally covers everything up to (but not including) the deposition of metal interconnect layers. Following the last FEOL operation, the result is typically a wafer with isolated transistors (e.g., without any wires).

Embodiments described herein may be directed to back end of line (BEOL) semiconductor processing and structures. BEOL is the second portion of IC fabrication where the individual devices (e.g., transistors, capacitors, resistors, etc.) are interconnected with wiring on the wafer, e.g., the metallization layer or layers. BEOL includes contacts, insulating layers (dielectrics), metal levels, and bonding sites for chip-to-package connections. In the BEOL part of the fabrication stage contacts (pads), interconnect wires, vias and dielectric structures are formed. For modern IC processes, more than 10 metal layers may be added in the BEOL.

Embodiments described below may be applicable to FEOL processing and structures, BEOL processing and structures, or both FEOL and BEOL processing and structures. In particular, although an exemplary processing scheme may be illustrated using a FEOL processing scenario, such approaches may also be applicable to BEOL processing. Likewise, although an exemplary processing scheme may be illustrated using a BEOL processing scenario, such approaches may also be applicable to FEOL processing.

One or more embodiments described herein are directed to structures and architectures for fabricating BEOL thin film transistors (TFTs) having relatively increased width relative to TFTs of conventional geometry. Embodiments may include or pertain to one or more of back end transistors, thin film transistors, and system-on-chip (SoC) technologies. One or more embodiments may be implemented to realize high performance backend transistors to potentially increase monolithic integration of backend logic plus memory in SoCs of future technology nodes.

In another aspect, one or more embodiments of the present disclosure are directed to methods for integrating RAM memory arrays into a logic processor, such as spin torque transfer random access memory (STTRAM) arrays, resistive random access memory (RRAM) arrays, or conductive bridge random access memory (CBRAM) memory arrays. Particular embodiments may be suitable for fabricating embedded non-volatile memory (e-NVM). Approaches described herein may provide a fabrication pathway for high performance RAM cells and increase the potential of using scaled RAM cells for future e-NVM needs, such as for integration in system on chip (SoC) products.

To provide context, there is increased need for advanced SoCs to include monolithically integrated BEOL transistors for logic functionality at higher metal layers. Such BEOL transistors typically have a lower thermal budget than front end transistors due to increased thermal sensitivity of backend materials. Also, the performance of such transistors may otherwise be severely hampered due to low channel mobility for BEOL-compatible channel materials such as polycrystalline silicon or IGZO (indium gallium zinc oxide).

In accordance with one or more embodiments described herein, multi-channel BEOL-compatible thin film transistors (TFTs) are fabricated by effectively increasing the transistor width (and hence the drive strength and performance) for a given projected area. A TFT fabricated using such an architecture may exhibit an increase in gate control, stability, and performance of thin film transistors. Applications of such systems may include, but are not limited to, back end (BEOL) logic, memory, or analog applications. Embodiments described herein may include non-planar structures that effectively increase transistor width (relative to a planar device) by integrating the devices in unique architectures.

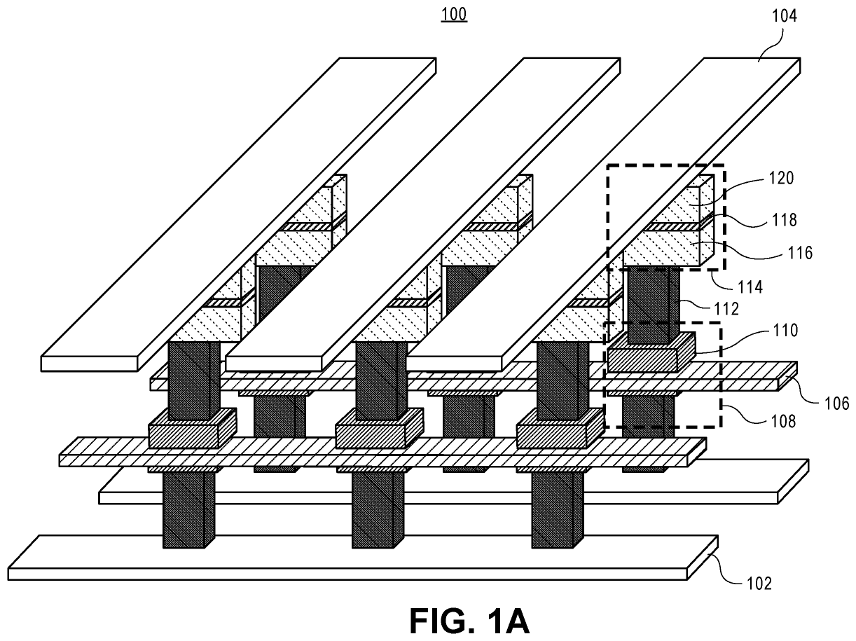

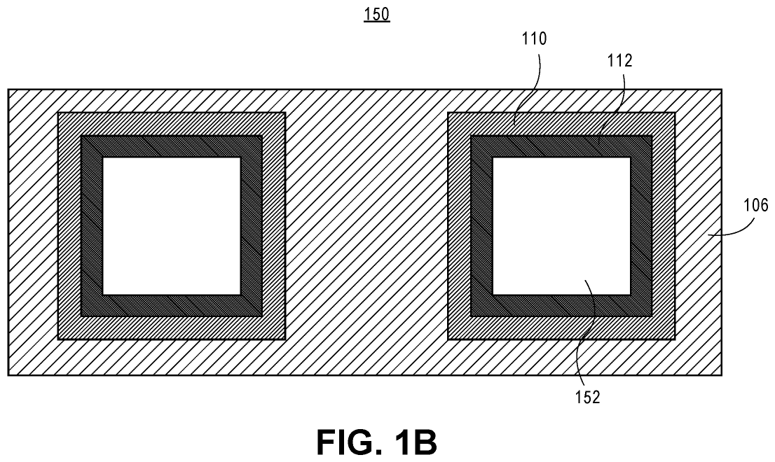

To provide a benchmark, FIG. 1A illustrates an angled view of a conventional one transistor one resistor (1T-1R) memory array 100. FIG. 1B illustrates a plan view of taken through a cross-section 150 of a pair of transistors of the array 100 of FIG. 1A.

Referring to FIGS. 1A and 1B, the array 100 includes a source line 102. A bit line 104 is above the source line 102. A word line or gate electrode 106 is between the bit line 104 is and the source line 102. A single transistor (1T) 108 includes a gate dielectric layer 110 surrounding a single channel region 112. A memory element (resistor 1R) 114 is above the transistor 108. The memory element 114 includes a first memory layer 116 (e.g., bottom electrode), a second memory layer 118 (e.g., switching layer), and a third memory layer 120 (e.g., top electrode). In an embodiment, as viewed in the cross-section 150, the single channel region 112 surrounds an isolation structure 152.

With reference to transistor 108, one of the critical challenges with the cell design of FIG. 1A is with respect to highly scaled cells. There may be insufficient current (e.g., poor switching yield) due to a short effective gate width/cell (Weff/cell) for the single channel transistor 108. Addressing such issues, in accordance with an embodiment of the present disclosure, vertical FETs having a multi-channel configuration are implemented to effectively increase the transistor width (and hence the drive strength and performance) for a given projected area.

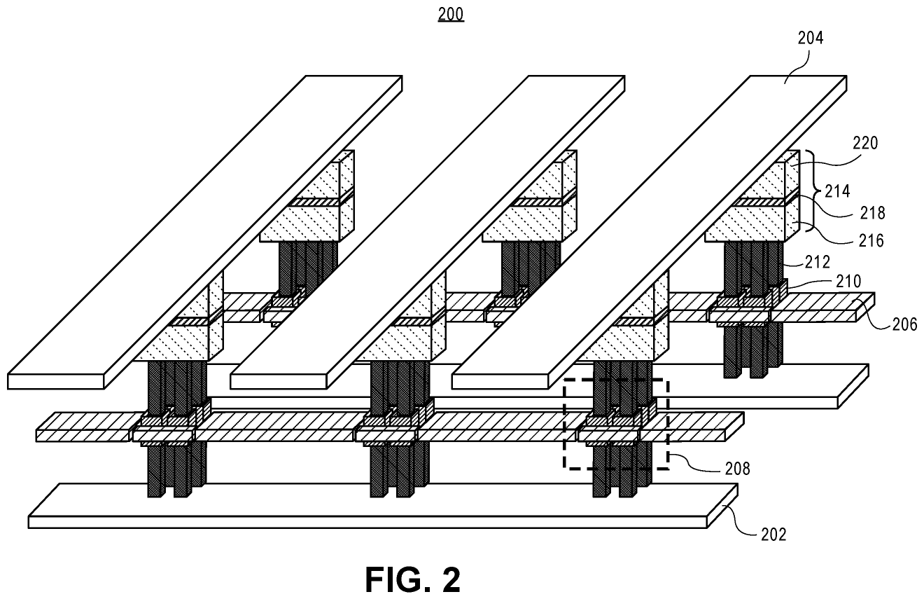

FIG. 2 illustrates an angled view of a one transistor one resistor (1T-1R) memory array, in accordance with an embodiment of the present disclosure.

Referring to FIG. 2, the array 200 includes a source line 202. A bit line 204 is above the source line 202. A word line or gate electrode 206 is between the bit line 204 is and the source line 202. A single transistor (1T) 208 includes a gate dielectric layer 210 surrounding a multi-channel region 212. A memory element (resistor 1R) 214 is above the transistor 208. The memory element 214 includes a first memory layer 216 (e.g., bottom electrode), a second memory layer 218 (e.g., switching layer), and a third memory layer 220 (e.g., top electrode). It is to be appreciated that array 200 may be included in an ILD layer or in a stack of ILD layers, which are not shown in FIG. 2 for ease of illustration.

Accordingly, in an embodiment, a memory array 200 includes a plurality of non-volatile random access memory (RAM) elements 214. The memory array 200 also includes a plurality of transistors 208. Individual ones of the plurality of transistors 208 are coupled to corresponding individual ones of the plurality of non-volatile RAM elements 214. The plurality of transistors 208 is a plurality of vertical multi-channel transistors.

In one embodiment, the plurality of non-volatile RAM elements 214 is a plurality of spin torque transfer random access memory (STTRAM) elements. In one embodiment, the plurality of non-volatile RAM elements 214 is a plurality of resistive random access memory (RRAM) elements. In one embodiment, the plurality of non-volatile RAM elements 214 is a plurality of conductive bridge random access memory (CBRAM) elements.

In one embodiment, the plurality of vertical multi-channel transistors 208 includes a polycrystalline silicon channel material. In one embodiment, the plurality of vertical multi-channel transistors 208 includes a polycrystalline group III-V channel material. In one embodiment, the plurality of vertical multi-channel transistors 208 includes a semiconducting oxide channel material.

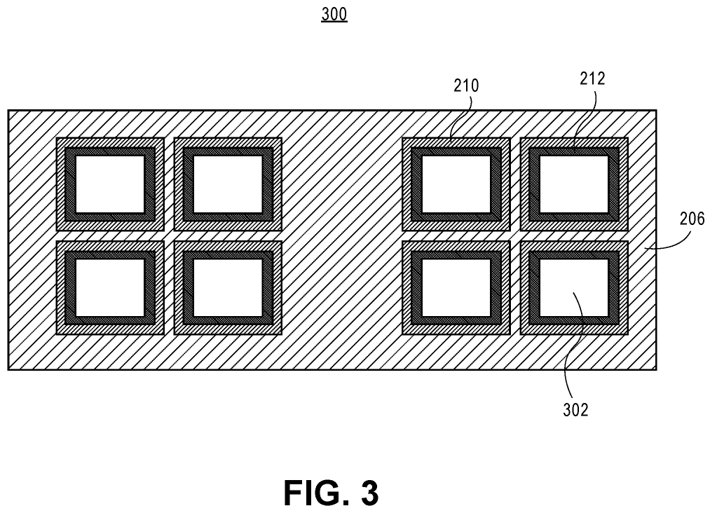

FIG. 3 illustrates a plan view of taken through a cross-section 300 of a pair of transistors of the array of FIG. 2, in accordance with an embodiment of the present disclosure. In an embodiment, as viewed in the cross-section 300, the multi-channel region 212 surrounds an isolation oxide structure 302.

Referring collectively to FIGS. 2 and 3, in an embodiment, an integrated circuit structure includes a bit line 204 above a source line 202. A transistor 208 is between the bit line 204 and the source line 202. The transistor 208 includes a vertical multi-channel structure 212. The vertical multi-channel structure 212 includes a plurality of discrete regions of a channel material. A non-volatile random access memory (RAM) element 214 is between the transistor 208 and the bit line 204. A gate dielectric layer 210 surrounds a portion of the vertical multi-channel structure 212. A word line (gate electrode) 206 surrounds the gate dielectric layer 210. The word line 206 is between the bit line 204 and the source line 202.

In an embodiment, the channel material is or includes polycrystalline silicon. In an embodiment, the channel material is or includes a polycrystalline group III-V material. In an embodiment, the channel material is or includes a semiconducting oxide material. In an embodiment, the vertical multi-channel structure 212 includes four discrete regions of the channel material, as is depicted in FIGS. 2 and 3. In other embodiments, the vertical multi-channel structure 212 includes two, three, or five or more discrete regions of the channel material.

Advantages of implementing a vertical multi-channel transistor in a 1T-1R memory array may provide for higher effective widths for the cell having a similar projected area as the array of FIG. 1A. High drive currents may be achieved for scaled cells, providing high switching yield. Also, lower cell-to-cell variability may be achieved by increasing the effective gate width (Weff).

Referring again to FIGS. 2 and 3, in an embodiment, the multi-channel 212 is composed of or includes a polycrystalline silicon layer. In one such embodiment, the gate dielectric layer 210 includes a layer of a high-k dielectric material directly on a silicon oxide layer on the polycrystalline silicon layer. In another embodiment, the multi-channel 212 is composed of or includes a polycrystalline germanium material layer or a polycrystalline silicon germanium material layer.

In another embodiment, the multi-channel 212 is composed of or includes a polycrystalline group III-V material layer. In a specific embodiment, the gate dielectric layer 210 includes a layer of a high-k dielectric material directly on the group III-V material layer.

In an alternative embodiment, the multi-channel 212 is composed of or includes is a semiconducting oxide material layer. In one such embodiment, the semiconducting oxide material layer includes indium gallium zinc oxide (IGZO). In one embodiment, the semiconducting oxide material layer includes a material selected from the group consisting of tin oxide, antimony oxide, indium oxide, indium tin oxide, titanium oxide, zinc oxide, indium zinc oxide, gallium oxide, titanium oxynitride, ruthenium oxide and tungsten oxide. In a specific embodiment, the gate dielectric layer 164 includes a layer of a high-k dielectric material directly on the semiconducting oxide material.

In an embodiment, with reference to FIGS. 2 and 3, the RAM bit cell or element 214 is a spin torque transfer random access memory (STTRAM) bit cell or element. In one such embodiment, the switching layer (or stack of layers including a switching layer) 218 is a stack of layers that is referred to as a magnetic tunnel junction (MTJ). In a specific such embodiment, the MTJ includes a fixed magnetic layer, a tunneling barrier layer, and a free magnetic layer. In another specific such embodiment, the MTJ includes a free magnetic layer, a tunneling barrier layer, and a fixed magnetic layer. The MTJ may utilize a phenomenon known as tunneling magnetoresistance (TMR).

For such a structure 214 including two ferromagnetic layers separated by a thin insulating tunnel layer, it is more likely that electrons will tunnel through the tunnel material layer when magnetizations of the two magnetic layers are in a parallel orientation than if they are not (non-parallel or antiparallel orientation). As such, the MTJ can be switched between two states of electrical resistance, one state having a low resistance and one state with a high resistance. The greater the differential in resistance, the higher the TMR ratio. The higher the TMR ratio, the more readily a bit can be reliably stored in association with the MTJ resistive state. MTJs with magnetic electrodes having a perpendicular (out of plane of substrate) magnetic easy axis have a potential for realizing higher density memory than in-plane variants, and may be referred to a pMTJ. In some embodiments, then, the MTJ is a perpendicular system, where spins of the magnetic layers are perpendicular to the plane of the material layers (e.g., the magnetic easy axis is in the z-direction out of the plane of substrate).

In the case of an MTJ, the fixed magnetic layer may be composed of a material or stack of materials suitable for maintaining a fixed magnetization direction while a free magnetic material layer is magnetically softer (e.g., magnetization can easily rotate to parallel and antiparallel state with respect to fixed layer). In an embodiment, the fixed magnetic layer is composed of a material or stack of materials suitable for maintaining a fixed majority spin. Thus, the fixed magnetic layer may be referred to as a ferromagnetic layer. In one embodiment, the fixed magnetic layer is composed of a single layer of cobalt iron boron (CoFeB). However, in another embodiment, the fixed magnetic layer is composed of a cobalt iron boron (CoFeB) layer, ruthenium (Ru) layer, cobalt iron boron (CoFeB) layer stack. In an embodiment, although not depicted, a synthetic antiferromagnet (SAF) is disposed on or adjacent the fixed magnetic layer.

In an embodiment, the dielectric or tunneling layer of an MTJ is composed of a material suitable for allowing current of a majority spin to pass through the layer, while impeding at least to some extent current of a minority spin to pass through the layer. Thus, the dielectric or tunneling layer (or spin filter layer) may be referred to as a tunneling layer. In one embodiment, the dielectric layer is composed of a material such as, but not limited to, magnesium oxide (MgO) or aluminum oxide (Al2O3). In one embodiment, the dielectric layer has a thickness of approximately 1 nanometer.

In an embodiment, the free magnetic layer of an MTJ is composed of a material suitable for transitioning between a majority spin and a minority spin, depending on the application. Thus, the free magnetic layer (or memory layer) may be referred to as a ferromagnetic memory layer. In one embodiment, the free magnetic layer is composed of a layer of cobalt iron (CoFe) or cobalt iron boron (CoFeB).

In an embodiment, the MTJ functions essentially as a resistor, where the resistance of an electrical path through the MTJ may exist in two resistive states, either “high” or “low,” depending on the direction or orientation of magnetization in the free magnetic layer and in the fixed magnetic layer. In the case that the spin direction is of minority in the free magnetic layer, a high resistive state exists, where direction of magnetization in the free magnetic layer and the fixed magnetic layer are substantially opposed or anti-parallel with one another. In the case that the spin direction is of majority in the free magnetic layer, a low resistive state exists, where the direction of magnetization in the free magnetic layer and the fixed magnetic layer is substantially aligned or parallel with one another. It is to be appreciated that the terms “low” and “high” with regard to the resistive state of the MTJ are relative to one another. In other words, the high resistive state is merely a detectibly higher resistance than the low resistive state, and vice versa. Thus, with a detectible difference in resistance, the low and high resistive states can represent different bits of information (i.e. a “0” or a “1”).

Thus, the MTJ may store a single bit of information (“0” or “1”) by its state of magnetization. The information stored in the MTJ is sensed by driving a current through the MTJ. The free magnetic layer does not require power to retain its magnetic orientations. As such, the state of the MTJ is preserved when power to the device is removed. Therefore, a memory bit cell 214 is, in an embodiment, non-volatile. In accordance with an embodiment of the present disclosure, each bit of data is stored in a separate magnetic tunnel junction (MTJ). To write information in a STT-MRAM device, the spin transfer torque effect is used to switch the free layer from the parallel to anti-parallel state and vice versa. The passing of current through the MTJ produces spin polarized current, which results in a torque being applied to the magnetization of the free layer. When the spin polarized current is sufficiently strong, enough torque is applied to the free layer to cause its magnetic orientation to change, thus allowing for bits to be written. To read the stored bit, sensing circuitry measures the resistance of the MTJ.

Referring again to FIG. 2, in an embodiment in which the RAM bit cell or element 214 is a spin torque transfer random access memory (STTRAM) bit cell or element, the lower electrode 216 includes a metal alloy layer, such as a titanium nitride (TiN) layer or a tantalum nitride (TaN) layer. In an embodiment, the upper electrode 220 is a topographically smooth electrode. In one such embodiment, upper top electrode 220 has a thickness suitable for good conductivity but has little to no columnar structure formation that would otherwise lead to a rough top surface. Such a topographically smooth electrode may be referred to as amorphous in structure. In a specific embodiment, the upper electrode 220 is composed of Ru layers interleaved with Ta layers. In alternative embodiments, however, the upper electrode 220 is a conventional single metal electrode, such as a Ta or Ru electrode.

In another embodiment, with reference to FIG. 2, the RAM bit cell or element 214 is a resistive random access memory (RRAM) bit cell or element. Nonvolatile memory based on resistance change is known as RRAM. In an embodiment, the switching layer 218 is an anionic-based conductive oxide layer. In one such embodiment, one electrode (lower electrode 216 or upper electrode 220) in a memory element including the anionic-based conductive oxide layer 218 is a noble metal based electrode, while the other electrode (upper electrode 220 or lower electrode 216, respectively) is a transition metal for which some of the lower valence oxides are conductive (e.g., to act as an oxygen reservoir). That is, when oxygen atoms migrate to the transition metal oxide, the resulting interfacial transition metal oxide formed remains conductive. Examples of suitable transition metals which form conductive oxides include but are not limited to, W, V, Cr, or Ir. In an embodiment, examples of suitable noble metals include, but are not limited to Pd or Pt. In other embodiments, one or both of the electrodes 216 and 220 is fabricated from an electro-chromic material. In other embodiments, one or both of the electrodes 216 and 220 is fabricated from a second, different conductive oxide material.

In an embodiment, for an RRAM bit cell or element, examples of suitable conductive oxides for switching layer 218 include, but are not limited to HfOx or TaOx. In another embodiment, the conductive oxide layer is composed of a material with two or more metal elements (e.g., as contrasted to common RRAM memories using one metal such as found in binary oxides, such as HfOx or TaOx). For example, in an embodiment, the switching layer 218 includes a material such as, but not limited to, ITO (In2O3−xSnO2−x), In2O3−x, sub-stoichiometric yttria doped zirconia (Y2O3−xZrO2−x), or La1−xSrxGa1−yMgyO3−X−0.5(x+y). In such ternary, quaternary, etc. alloys, the metals used are from adjacent columns of the periodic table. Specific examples of suitable such conductive oxides include, but are not limited to: Y and Zr in Y2O3−xZrO2−x, In and Sn in In2O3−xSnO2−x, or Sr and La in La1−xSrxGa1−yMgyO3. Such materials may be viewed as compositions selected to have aliovalent substitution to significantly increase the number of oxygen vacancies.

In an embodiment, with reference to FIG. 2, the RAM bit cell or element 214 is a conductive bridge random access memory (CBRAM) bit cell or element. It is to be appreciated that CBRAM may be viewed as a specific type of resistive random access memory (RRAM). In a CBRAM device, a filament may be formed based on metallic migration into an electrolyte material which is the switching layer of the CBRAM device. By contrast, in conventional RRAM, a filament may be created based on oxygen vacancies.

In an embodiment, for a CBRAM bit cell or element, the resistance switching layer 218 is composed of a solid electrolyte material. An electrolyte or solid electrolyte, as used herein, refers to solid electrolyte material which is a solid substance that receives ions, provides ions, or can transport ions. In an exemplary embodiment, the solid electrolyte material is a chalcogenide material. In another embodiment, the resistance switching layer 218 is composed of a metal oxide, such as hafnium oxide.

In an embodiment, in the case of a CBRAM bit cell or element, the lower electrode 216 (or, alternatively, the upper electrode 220) is an active electrode layer. The active electrode layer may be a source of cations for filament formation or resistance change in the switching layer 216. In an embodiment, the active electrode layer includes a metal species such as, but not limited to, copper, silver, nickel, or lithium. In an embodiment, the upper electrode 220 (or, alternatively, the lower electrode 216 in the case that the upper electrode 220 is an active electrode) is a passive electrode layer. The passive electrode layer may not be a source of cations for filament formation or resistance change in the switching layer 218. In an embodiment, the passive electrode layer includes a metal species such as, but not limited to, tungsten or platinum. In one embodiment, a metal nitride, such as a titanium nitride or a tantalum nitride layer, is used as the material for the passive electrode layer. In another embodiment, the passive electrode layer is composed of a noble metal such as, but not limited to Pd or Pt.

In accordance with an embodiment of the present disclosure, the above TFT non-planar architecture 208 provides for higher effective widths for a transistor for a scaled projected area. In an embodiment, the drive strength and performance of such transistors are improved over state-of-the-art planar BEOL transistors.

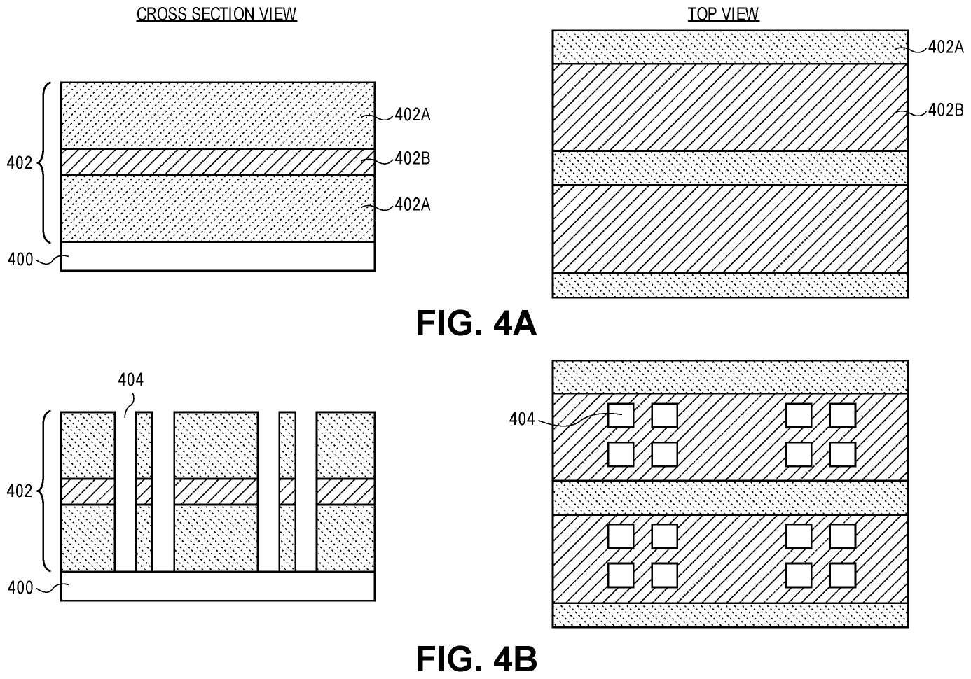

As an exemplary processing scheme, FIGS. 4A-4D illustrate cross-sectional and corresponding plan views of various stages in a method of fabricating a multi-channel vertical transistors, in accordance with an embodiment of the present disclosure.

Referring to FIG. 4A, a stack 402 of dielectric layers 402A/402B is formed above a substrate 400 and, possibly, on an insulating layer formed on or above the substrate 400. The stack 402 of dielectric layers includes alternating dielectric layers 404A and 404B of differing composition. In one embodiment, the stack 402 of dielectric layers is a stack of alternating silicon dioxide and silicon nitride layers. In an embodiment, the stack 402 is itself patterned as alternating layers, as taken along the plan view.

Referring to FIG. 4B, openings 404 are formed in the stack 402 of dielectric layers. In one embodiment, openings 404 are fabricated as a grating structure, where the term “grating” is used herein to refer to a tight pitch grating structure. In one such embodiment, the tight pitch is not achievable directly through conventional lithography. For example, a pattern based on conventional lithography may first be formed, but the pitch may be halved by the use of spacer mask patterning, as is known in the art. Even further, the original pitch may be quartered by a second round of spacer mask patterning. Accordingly, the grating-like patterns described herein may have dielectric fins spaced at a constant pitch and having a constant width. The pattern may be fabricated by a pitch halving or pitch quartering, or other pitch division, approach.

Referring to FIG. 4C, a gate dielectric layer 210 is formed within the openings 404. In an embodiment, the gate dielectric layer 210 is formed using an atomic layer deposition (ALD) process.

Referring to FIG. 4D, a channel material 212 is formed within the openings 404 and on the gate dielectric layer 210. In an embodiment, the channel material 212 is formed using an atomic layer deposition (ALD) process or a chemical vapor deposition (CVD) process. An insulating structure 302 may then be formed in the openings 404 on the channel material 212. In an embodiment, the insulating structure 302 is formed using a chemical vapor deposition (CVD) process followed by a chemical mechanical planarization (CMP) process. The structure of FIG. 4D may be included as a portion of the array 200 described in association with FIG. 2.

It is to be appreciated that the layers and materials described in association with embodiments herein are typically formed on or above an underlying semiconductor substrate, such as substrate 400, e.g., as FEOL layer(s). In other embodiments, the layers and materials described in association with embodiments herein are typically formed on or above underlying device layer(s) of an integrated circuit, e.g., as BEOL layer(s) above an underlying semiconductor substrate, such as substrate 400. In an embodiment, an underlying semiconductor substrate represents a general workpiece object used to manufacture integrated circuits. The semiconductor substrate often includes a wafer or other piece of silicon or another semiconductor material. Suitable semiconductor substrates include, but are not limited to, single crystal silicon, polycrystalline silicon and silicon on insulator (SOI), as well as similar substrates formed of other semiconductor materials. The semiconductor substrate, depending on the stage of manufacture, often includes transistors, integrated circuitry, and the like. The substrate may also include semiconductor materials, metals, dielectrics, dopants, and other materials commonly found in semiconductor substrates. Furthermore, although not depicted, structures described herein may be fabricated on underlying lower level back end of line (BEOL) interconnect layers.

In the case that an insulator layer is optionally used between the substrate and a memory array, the insulator layer may be composed of a material suitable to ultimately electrically isolate, or contribute to the isolation of, multi-channel vertical transistors from an underlying bulk substrate or interconnect layer. For example, in one embodiment, the insulator layer is composed of a dielectric material such as, but not limited to, silicon dioxide, silicon oxy-nitride, silicon nitride, or carbon-doped silicon nitride. In a particular embodiment, the insulator layer is a low-k dielectric layer of an underlying BEOL layer.

In an embodiment, gate electrode 206 (e.g., word line) is composed of an interconnect material described below. In other embodiment, gate electrode 206 includes at least one P-type work function metal or N-type work function metal. For a P-type transistors, metals that may be used for the gate electrode 206 may include, but are not limited to, ruthenium, palladium, platinum, cobalt, nickel, and conductive metal oxides (e.g., ruthenium oxide). For an N-type transistor, metals that may be used for the gate electrode 206 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode includes a stack of two or more metal layers, where one or more metal layers are work function metal layers and at least one metal layer is a fill metal layer. Further metal layers may be included for other purposes, such as to act as a barrier layer.

In an embodiment, gate dielectric layer 210 is composed of a high-K material. For example, in one embodiment, the gate dielectric layer 210 is composed of a material such as, but not limited to, hafnium oxide, hafnium oxy-nitride, hafnium silicate, lanthanum oxide, zirconium oxide, zirconium silicate, tantalum oxide, barium strontium titanate, barium titanate, strontium titanate, yttrium oxide, aluminum oxide, lead scandium tantalum oxide, lead zinc niobate, or a combination thereof.

In some embodiments, the channel material 212 is a semiconducting oxide material in contact with the gate dielectric layer 210, an arrangement which may put an IGZO layer in contact with a high-k metal oxide layer. In other embodiments, an intermediate material is disposed between a semiconducting oxide material and a gate dielectric layer. In some embodiments, an IGZO layer includes multiple regions of IGZO having different material properties. For example, an IGZO layer may include low indium content IGZO close to (e.g., in contact with) a high-k gate dielectric layer, and a high indium content IGZO close to (e.g., in contact with) the higher mobility semiconducting oxide channel material. High indium content IGZO may provide higher mobility and poorer interface properties relative to low indium content IGZO, while low indium content IGZO may provide a wider band gap, lower gate leakage, and better interface properties, although a lower mobility, relative to high indium content IGZO.

In an embodiment, the isolation structure 302 is composed of a dielectric material such as, but not limited to, silicon dioxide, silicon oxy-nitride, silicon nitride, or carbon-doped silicon nitride. In an embodiment, the isolation structure 302 is composed of a low-k dielectric material.

In an embodiment, source line 202 and bit line 204 are composed of one or more metal or metal-containing conductive structures. Such conductive interconnect lines are also sometimes referred to in the art as traces, wires, lines, metal, interconnect lines or simply interconnects. In a particular embodiment, each of the interconnect lines includes a barrier layer and a conductive fill material. In an embodiment, the barrier layer is composed of a metal nitride material, such as tantalum nitride or titanium nitride. In an embodiment, the conductive fill material is composed of a conductive material such as, but not limited to, Cu, Al, Ti, Zr, Hf, V, Ru, Co, Ni, Pd, Pt, W, Ag, Au or alloys thereof.

Interconnect lines, such as, source line 202 and bit line 204, described herein may be fabricated as a grating structure, where the term “grating” is used herein to refer to a tight pitch grating structure. In one such embodiment, the tight pitch is not achievable directly through conventional lithography. For example, a pattern based on conventional lithography may first be formed, but the pitch may be halved by the use of spacer mask patterning, as is known in the art. Even further, the original pitch may be quartered by a second round of spacer mask patterning. Accordingly, the grating-like patterns described herein may have conductive lines spaced at a constant pitch and having a constant width. The pattern may be fabricated by a pitch halving or pitch quartering, or other pitch division, approach.

In an embodiment, ILD materials described herein, such as an ILD layer or layers surrounding the structure of FIG. 2, are composed of or include a layer of a dielectric or insulating material. Examples of suitable dielectric materials include, but are not limited to, oxides of silicon (e.g., silicon dioxide (SiO2)), doped oxides of silicon, fluorinated oxides of silicon, carbon doped oxides of silicon, various low-k dielectric materials known in the arts, and combinations thereof. The interlayer dielectric material may be formed by conventional techniques, such as, for example, chemical vapor deposition (CVD), physical vapor deposition (PVD), or by other deposition methods.

In an embodiment, as is also used throughout the present description, lithographic operations are performed using 193 nm immersion lithography (i193), extreme ultra-violet (EUV) and/or electron beam direct write (EBDW) lithography, or the like. A positive tone or a negative tone resist may be used. In one embodiment, a lithographic mask is a trilayer mask composed of a topographic masking portion, an anti-reflective coating (ARC) layer, and a photoresist layer. In a particular such embodiment, the topographic masking portion is a carbon hardmask (CHM) layer and the anti-reflective coating layer is a silicon ARC layer.

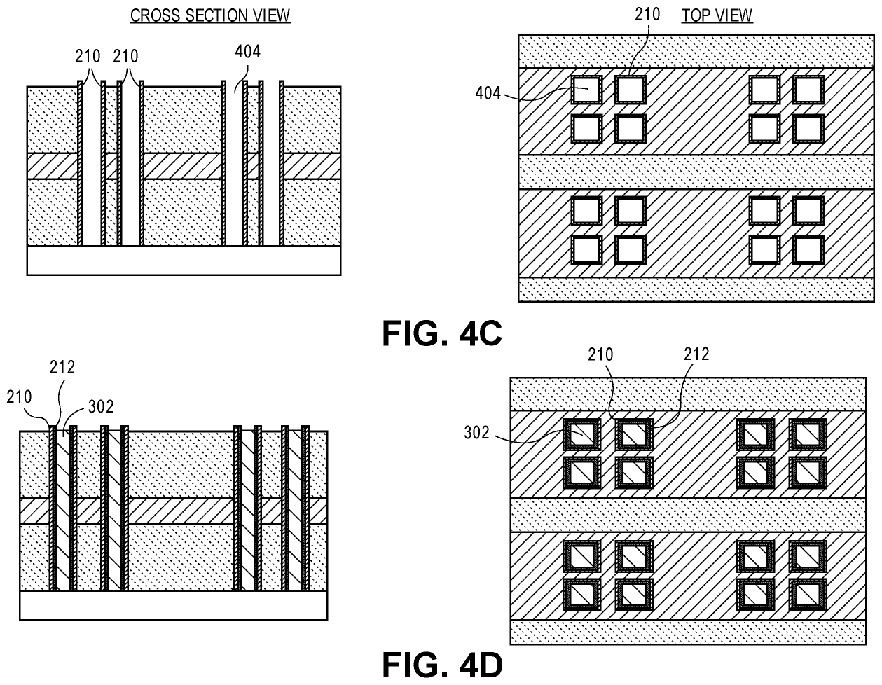

In another aspect, the integrated circuit structures described herein may be included in an electronic device. As a first example of an apparatus that may include one or more of the TFTs disclosed herein, FIGS. 5A and 5B are top views of a wafer and dies that include multi-channel vertical transistors, in accordance with any of the embodiments disclosed herein.

Referring to FIGS. 5A and 5B, a wafer 500 may be composed of semiconductor material and may include one or more dies 502 having integrated circuit (IC) structures formed on a surface of the wafer 500. Each of the dies 502 may be a repeating unit of a semiconductor product that includes any suitable IC (e.g., ICs including multi-channel vertical transistors). After the fabrication of the semiconductor product is complete (e.g., after manufacture of a multi-channel one transistor one resistor (1T-1R) memory array, the wafer 500 may undergo a singulation process in which each of the dies 502 is separated from one another to provide discrete “chips” of the semiconductor product. In particular, devices that include TFT as disclosed herein may take the form of the wafer 500 (e.g., not singulated) or the form of the die 502 (e.g., singulated). The die 502 may include one or more transistors and/or supporting circuitry to route electrical signals to the transistors, as well as any other IC components. In some embodiments, the wafer 500 or the die 502 may include a memory device (e.g., a static random access memory (SRAM) device), a logic device (e.g., an AND, OR, NAND, or NOR gate), or any other suitable circuit element. Multiple ones of these devices may be combined on a single die 502. For example, a memory array formed by multiple memory devices may be formed on a same die 502 as a processing device or other logic that is configured to store information in the memory devices or execute instructions stored in the memory array.

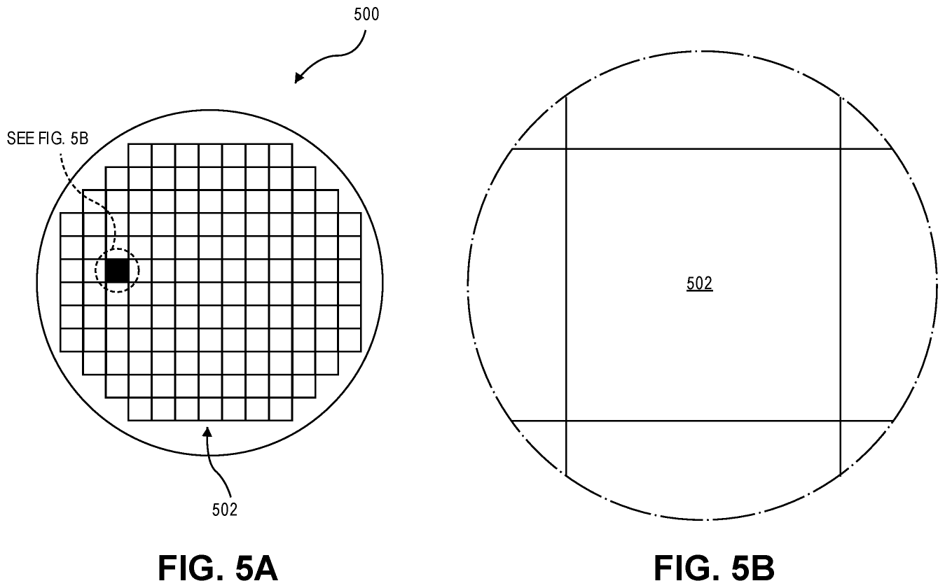

It is to be appreciated that an RAM material stack may be used to fabricate a memory bit cell. For example, FIG. 6 illustrates a schematic of a memory bit cell 600 which includes a random access memory (RAM) memory element, in accordance with an embodiment of the present disclosure. Such an RAM memory element may be suitable for manufacture on a substrate in common with logic regions of the substrate.

Referring to FIG. 6, the RAM memory element 670 includes a lower electrode 672 with a switching layer 674 (or stack of layers including a switching layer) above the lower electrode 672. An upper electrode 676 is above the switching layer 674 (or stack of layers including a switching layer). It is to be appreciated that the RAM element 670 may include the material layers described in association with RAM element 214 described in association with FIG. 2. In an embodiment, the RAM memory element 670 is an STTRAM element, an RRAM element, or a CBRAM element.

The upper electrode 676 may be electrically connected to a bit line 632. The lower electrode 672 may be coupled with a transistor 634, which may be a multi-channel transistor. The transistor 634 may be coupled with a word line 636 and a source line 638 in a manner that will be appreciated by those skilled in the art. The memory bit cell 600 may further include additional read and write circuitry (not shown), a sense amplifier (not shown), a bit line reference (not shown), and the like, as will be appreciated by those skilled in the art, for the operation of the memory bit cell 600. It is to be appreciated that a plurality of the memory bit cells 600 may be operably connected to one another to form a memory array, where the memory array can be incorporated into a non-volatile memory region of a substrate in common with a logic region. It is to be appreciated that the transistor 634 may be connected to the upper electrode 676 or the lower electrode 672, although only the latter is shown. Likewise, bit line 632 may be connected to the lower electrode 672 or the upper electrode 676, although only the latter is shown.

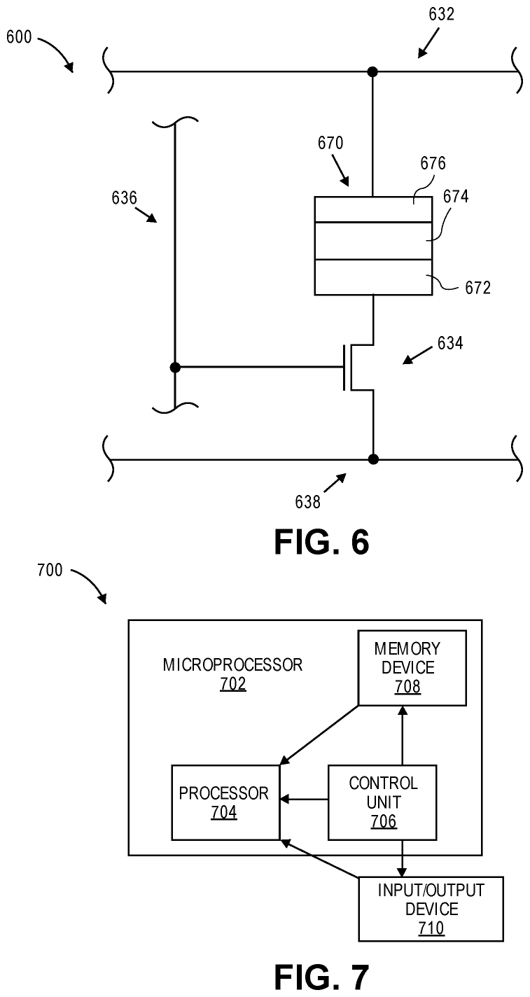

FIG. 7 illustrates a block diagram of an electronic system 700, in accordance with an embodiment of the present disclosure. The electronic system 700 can correspond to, for example, a portable system, a computer system, a process control system, or any other system that utilizes a processor and an associated memory. The electronic system 700 may include a microprocessor 702 (having a processor 704 and control unit 706), a memory device 708, and an input/output device 710 (it is to be appreciated that the electronic system 700 may have a plurality of processors, control units, memory device units and/or input/output devices in various embodiments). In one embodiment, the electronic system 700 has a set of instructions that define operations which are to be performed on data by the processor 704, as well as, other transactions between the processor 704, the memory device 708, and the input/output device 710. The control unit 706 coordinates the operations of the processor 704, the memory device 708 and the input/output device 710 by cycling through a set of operations that cause instructions to be retrieved from the memory device 708 and executed. The memory device 708 can include a memory element as described in the present description. In an embodiment, the memory device 708 is embedded in the microprocessor 702, as depicted in FIG. 7. In an embodiment, the processor 704, or another component of electronic system 700, includes an array of random access memory (RAM) devices, such as those described herein.

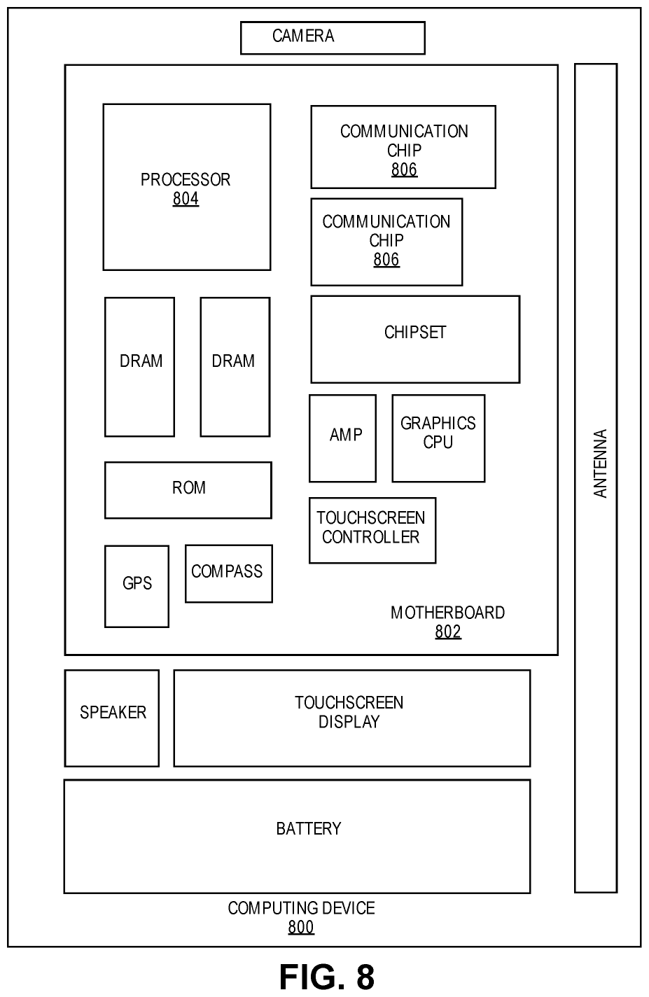

FIG. 8 illustrates a computing device 800 in accordance with one embodiment of the disclosure. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processsor 804.

Depending on its applications, computing device 800 may include other components that may or may not be physically and electrically coupled to the board 802. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of embodiments of the disclosure, the integrated circuit die of the processor includes one or more arrays, such as multi-channel one transistor one resistor (1T-1R) memory arrays, built in accordance with embodiments of the present disclosure. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of an embodiment of the disclosure, the integrated circuit die of the communication chip includes multi-channel one transistor one resistor (1T-1R) memory arrays, built in accordance with embodiments of the present disclosure.

In further implementations, another component housed within the computing device 800 may contain a stand-alone integrated circuit memory die that includes one or more arrays, such as multi-channel one transistor one resistor (1T-1R) memory arrays, built in accordance with embodiments of the present disclosure.

In various implementations, the computing device 800 may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device 800 may be any other electronic device that processes data.

Accordingly, one or more embodiments of the present disclosure relate generally to the fabrication of embedded microelectronic memory. The microelectronic memory may be non-volatile, where the memory can retain stored information even when not powered. One or more embodiments of the present disclosure relate to the fabrication of spin torque transfer random access memory (STTRAM), resistive random access memory (RRAM), or conductive bridge random access memory (CBRAM) memory arrays integrated into a logic processor. Such arrays may be used in an embedded non-volatile memory, either for its non-volatility, or as a replacement for embedded dynamic random access memory (eDRAM). For example, such an array may be used for 1T-1X memory or 2T-1X memory (X=magneto-based switching device or resistor-based switching device) at competitive cell sizes within a given technology node.

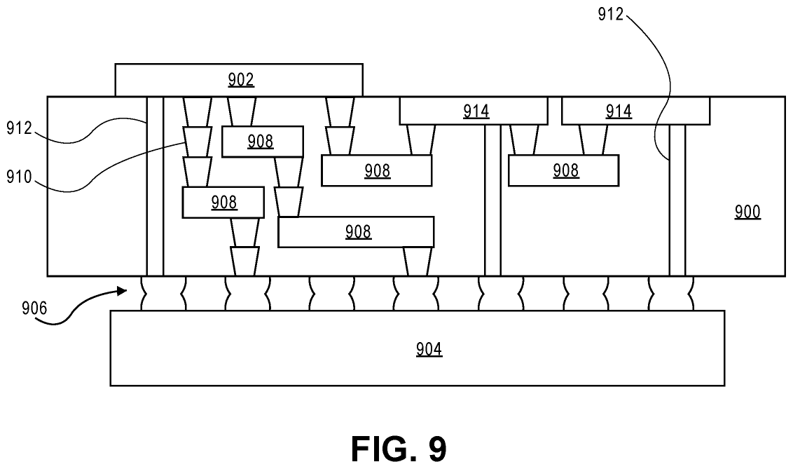

FIG. 9 illustrates an interposer 900 that includes one or more embodiments of the disclosure. The interposer 900 is an intervening substrate used to bridge a first substrate 902 to a second substrate 904. The first substrate 902 may be, for instance, an integrated circuit die. The second substrate 904 may be, for instance, a memory module, a computer motherboard, or another integrated circuit die. Generally, the purpose of an interposer 900 is to spread a connection to a wider pitch or to reroute a connection to a different connection. For example, an interposer 900 may couple an integrated circuit die to a ball grid array (BGA) 906 that can subsequently be coupled to the second substrate 904. In some embodiments, the first and second substrates 902/904 are attached to opposing sides of the interposer 900. In other embodiments, the first and second substrates 902/904 are attached to the same side of the interposer 900. And in further embodiments, three or more substrates are interconnected by way of the interposer 900.

The interposer 900 may be formed of an epoxy resin, a fiberglass-reinforced epoxy resin, a ceramic material, or a polymer material such as polyimide. In further implementations, the interposer may be formed of alternate rigid or flexible materials that may include the same materials described above for use in a semiconductor substrate, such as silicon, germanium, and other group III-V and group IV materials.

The interposer may include metal interconnects 908 and vias 910, including but not limited to through-silicon vias (TSVs) 912. The interposer 900 may further include embedded devices 914, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 900. In accordance with embodiments of the disclosure, apparatuses or processes disclosed herein may be used in the fabrication of interposer 900.

Thus, embodiments described herein include multi-channel vertical transistors for embedded non-volatile memory.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

### Example Embodiment 1

A memory array includes a plurality of non-volatile random access memory (RAM) elements. The memory array also includes a plurality of transistors. Individual ones of the plurality of transistors are coupled to corresponding individual ones of the plurality of non-volatile RAM elements. The plurality of transistors is a plurality of vertical multi-channel transistors.

### Example Embodiment 2

The memory array of example embodiment 1, wherein the plurality of non-volatile RAM elements is a plurality of spin torque transfer random access memory (STTRAM) elements.

### Example Embodiment 3

The memory array of example embodiment 1, wherein the plurality of non-volatile RAM elements is a plurality of resistive random access memory (RRAM) elements.

### Example Embodiment 4

The memory array of example embodiment 1, wherein the plurality of non-volatile RAM elements is a plurality of conductive bridge random access memory (CBRAM) elements.

### Example Embodiment 5

The memory array of example embodiment 1, 2, 3 or 4, wherein the plurality of vertical multi-channel transistors includes a polycrystalline silicon channel material.

### Example Embodiment 6

The memory array of example embodiment 1, 2, 3 or 4, wherein the plurality of vertical multi-channel transistors includes a polycrystalline group III-V channel material.

### Example Embodiment 7

The memory array of example embodiment 1, 2, 3 or 4, wherein the plurality of vertical multi-channel transistors includes a semiconducting oxide channel material.

### Example Embodiment 8

An integrated circuit structure includes a bit line above a source line. A transistor is between the bit line and the source line. The transistor includes a vertical multi-channel structure. The vertical multi-channel structure includes a plurality of discrete regions of a channel material. A non-volatile random access memory (RAM) element is between the transistor and the bit line. A gate dielectric layer surrounds a portion of the vertical multi-channel structure. A word line surrounds the gate dielectric layer, the word line between the bit line and the source line.

### Example Embodiment 9

The integrated circuit structure of claim 8, wherein the non-volatile RAM element is a spin torque transfer random access memory (STTRAM) element.

### Example Embodiment 10

The integrated circuit structure of claim 8, wherein the non-volatile RAM element is a resistive random access memory (RRAM) element.

### Example Embodiment 11

The integrated circuit structure of claim 8, wherein the non-volatile RAM element is a conductive bridge random access memory (CBRAM) element.

### Example Embodiment 12

The integrated circuit structure of claim 8, 9, 10 or 11, wherein the channel material includes polycrystalline silicon.

### Example Embodiment 13

The integrated circuit structure of claim 8, 9, 10 or 11, wherein the channel material includes a polycrystalline group III-V material.

### Example Embodiment 14

The integrated circuit structure of claim 8, 9, 10 or 11, wherein the channel material includes a semiconducting oxide material.

### Example Embodiment 15

The integrated circuit structure of claim 8, 9, 10, 11, 12, 13 or 14, wherein the vertical multi-channel structure includes four discrete regions of the channel material.

### Example Embodiment 16

An integrated circuit structure includes a first interconnect line above a second interconnect line. A transistor is between the first interconnect line and the second interconnect line. The transistor includes a vertical multi-channel structure. The vertical multi-channel structure includes a plurality of discrete regions of a channel material. A gate dielectric layer surrounds a portion of the vertical multi-channel structure. A gate electrode surrounds the gate dielectric layer. The gate electrode is between the first interconnect line and the second interconnect line.

### Example Embodiment 17

The integrated circuit structure of example embodiment 16, wherein the channel material includes polycrystalline silicon.

### Example Embodiment 18

The integrated circuit structure of example embodiment 16, wherein the channel material includes a polycrystalline group III-V material.

### Example Embodiment 19

The integrated circuit structure of example embodiment 16, wherein the channel material includes a semiconducting oxide material.

### Example Embodiment 20

The integrated circuit structure of example embodiment 16, 17, 18 or 19, wherein the vertical multi-channel structure includes four discrete regions of the channel material.

What is claimed is:

1. A memory array, comprising:
a plurality of non-volatile random access memory (RAM) elements; and
a plurality of transistors, individual ones of the plurality of transistors coupled to corresponding individual ones of the plurality of non-volatile RAM elements, the plurality of transistors a plurality of vertical multi-channel transistors.

2. The memory array of claim 1, wherein the plurality of non-volatile RAM elements is a plurality of spin torque transfer random access memory (STTRAM) elements.

3. The memory array of claim 1, wherein the plurality of non-volatile RAM elements is a plurality of resistive random access memory (RRAM) elements.

4. The memory array of claim 1, wherein the plurality of non-volatile RAM elements is a plurality of conductive bridge random access memory (CBRAM) elements.

5. The memory array of claim 1, wherein the plurality of vertical multi-channel transistors comprises a polycrystalline silicon channel material.

6. The memory array of claim 1, wherein the plurality of vertical multi-channel transistors comprises a polycrystalline group III-V channel material.

7. The memory array of claim 1, wherein the plurality of vertical multi-channel transistors comprises a semiconducting oxide channel material.

8. An integrated circuit structure, comprising:
a bit line above a source line;
a transistor between the bit line and the source line, the transistor comprising a vertical multi-channel structure, the vertical multi-channel structure comprising a plurality of discrete regions of a channel material;
a non-volatile random access memory (RAM) element between the transistor and the bit line;
a gate dielectric layer surrounding a portion of the vertical multi-channel structure; and
a word line surrounding the gate dielectric layer, the word line between the bit line and the source line.

9. The integrated circuit structure of claim 8, wherein the non-volatile RAM element is a spin torque transfer random access memory (STTRAM) element.

10. The integrated circuit structure of claim 8, wherein the non-volatile RAM element is a resistive random access memory (RRAM) element.

11. The integrated circuit structure of claim 8, wherein the non-volatile RAM element is a conductive bridge random access memory (CBRAM) element.

12. The integrated circuit structure of claim 8, wherein the channel material comprises polycrystalline silicon.

13. The integrated circuit structure of claim 8, wherein the channel material comprises a polycrystalline group III-V material.

14. The integrated circuit structure of claim 8, wherein the channel material comprises a semiconducting oxide material.

15. The integrated circuit structure of claim 8, wherein the vertical multi-channel structure comprises four discrete regions of the channel material.

16. An integrated circuit structure, comprising:
a first interconnect line above a second interconnect line;
a transistor between the first interconnect line and the second interconnect line, the transistor comprising a vertical multi-channel structure, the vertical multi-channel structure comprising a plurality of discrete regions of a channel material;
a gate dielectric layer surrounding a portion of the vertical multi-channel structure; and
a gate electrode surrounding the gate dielectric layer, the gate electrode between the first interconnect line and the second interconnect line.

17. The integrated circuit structure of claim 16, wherein the channel material comprises polycrystalline silicon.

18. The integrated circuit structure of claim 16, wherein the channel material comprises a polycrystalline group III-V material.

19. The integrated circuit structure of claim 16, wherein the channel material comprises a semiconducting oxide material.

20. The integrated circuit structure of claim 16, wherein the vertical multi-channel structure includes four discrete regions of the channel material.
